(19) United States
(12) Patent Application Publication
(10) Pub. No.: US 2008/0192449 A1
(43) Pub. Date: Aug. 14, 2008

(54) ELECTRIC CIRCUIT PACKAGE

(76) Inventors: Dong-Churl Kim, Ansan-si (KR); Shi-Yun Cho, Anyang-si (KR); Hong-Kweun Kim, Ansan-si (KR); Kyu-Sub Kwak, Seoul (KR); Kyung-Wan Park, Suwon-si (KR); Seung-Woo Han, Seoul (KR)

Correspondence Address: CHA & REITER, LLC, 210 ROUTE 4 EAST STE 103, PARAMUS, NJ, 07652, US

(21) Appl. No.: 12/028,864

(22) Filed: Feb. 11, 2008

(30) Foreign Application Priority Data
Feb. 12, 2007 (KR) 2007-14368

(51) Int. Cl. H05K 7/00

(52) U.S. Cl. 361/760

(57) ABSTRACT

An electric circuit package includes: a printed circuit substrate having an insulating layer and conductive pattern layers formed on an upper surface of the insulating layer; at least one of electronic parts disposed on an upper surface of the printed circuit substrate; at least one of conductive pins electrically connected to an conductive pattern layer providing grounding among the conductive pattern layers; and a molding member formed on the insulating layer in such a manner that the conductive pins and the electric parts are buried in the molding member, wherein each conductive pin has an upper surface exposed to an upper part of the molding member.

### CLAIM OF PRIORITY

This application claims priority to an application entitled “Electric circuit package,” filed in the Korean Intellectual Property Office on Feb. 12, 2007 and assigned Serial No. 2007-14368, the contents of which are hereby incorporated by reference.

### BACKGROUND OF THE INVENTION

1. Field of the Invention

The present invention relates to an electric circuit package in which a plurality of electric devices are integrated therein, and more particularly to an electric circuit package having an electromagnetic wave shielding means.

2. Description of the Related Art

An electric circuit package is a System in Package (SiP) structure having a plurality of electric parts integrated therein. Particularly, when a device generating many electromagnetic waves, such as a radio frequency integrated circuit (RFIC), is included therein, the electric circuit package needs an electromagnetic wave shielding means.

The electromagnetic shielding means can use a metallic can surrounding an exterior of a module. A structure that electric parts are mounted in the metallic can has been proposed. However, this type of conventional electric circuit packages is used to restrain electromagnetic waves from escaping outside or flowing inside, but it is difficult to shield electromagnetic waves generated in interior devices. Furthermore, when a metallic can for shielding electromagnetic waves is included in the conventional electric circuit package, it is limited to employ the metallic can in a magnified printed circuit substrate.

### SUMMARY OF THE INVENTION

Accordingly, the present invention has been made to solve the above-mentioned problems occurring in the prior art and provides additional advantages, by providing an electric circuit package which can minimize high-integration and generation of electromagnetic wave interference between respective devices.

In accordance with an aspect of the present invention, an electric circuit package includes: a printed circuit substrate having an insulating layer and conductive pattern layers formed on an upper surface of the insulating layer; at least one of electronic parts disposed on an upper surface of the printed circuit substrate; at least one of conductive pins electrically coupled to an conductive pattern layer providing grounding among the conductive pattern layers; and a molding member formed on the insulating layer in such a manner that the conductive pins and the electric parts are buried in the molding member, wherein each conductive pin has an upper surface exposed to an upper part of the molding member.

### BRIEF DESCRIPTION OF THE DRAWINGS

The above and other aspects, features and advantages of the present invention will be more apparent from the following detailed description taken in conjunction with the accompanying drawings, in which:

FIG. 1 is a sectional view illustrating an electric circuit package according to an exemplary embodiment of the present invention.

### DETAILED DESCRIPTION OF THE INVENTION

Hereinafter, exemplary embodiments of the present invention will be described with reference to the accompanying drawings. For the purposes of clarity and simplicity, a detailed description of known functions and configurations incorporated herein will be omitted when it may make the subject matter of the present invention unclear.

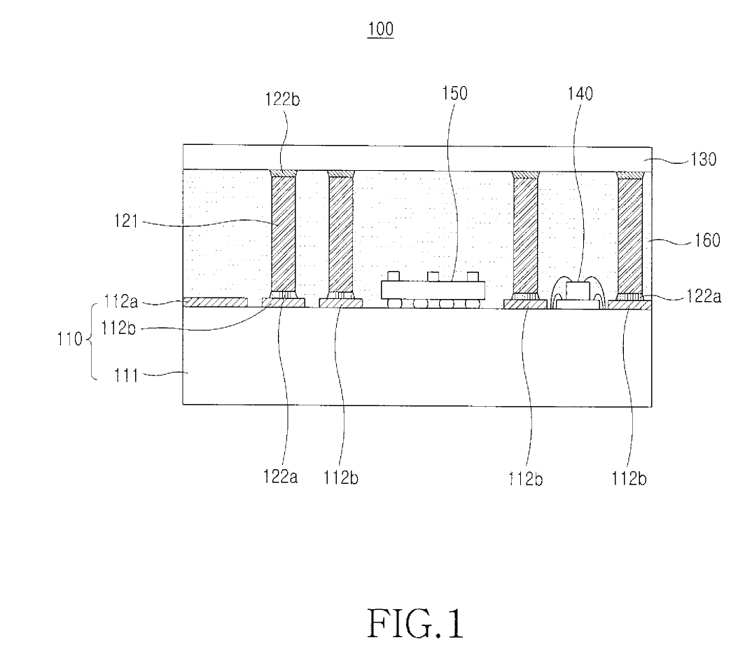

FIG. 1 is a sectional view illustrating an electric circuit package according to an exemplary embodiment of the present invention. As shown, an electric circuit package 100 according to the present embodiment includes a printed circuit substrate 110, electric parts 140 and 150 disposed on an upper surface of the printed circuit substrate 110, at least one conductive pin 121, a molding member 160 having the conductive pins 121 and the electric parts 140 and 150 buried therein, and a conductive plate 130.

The printed circuit substrate 110 includes an insulating layer 111 such as a core, and conductive pattern layers 112a and 112b formed by etching plates of conductive metallic material, such as Cu, formed on the insulating layer 111. The electric parts 140 and 150 are disposed on the upper surface of the printed circuit substrate 110, and can be electrically connected to the conductive pattern layers 112a and 112b by soldering or wiring, etc.

The conductive pattern layers 112a and 112b provide circuit wirings of electric parts to be integrated, and may include circuit wirings 112a for providing a power or a signal and data process, and ground wiring 112b for grounding.

The conductive pins 121 can be electrically connected to the ground wiring 112b, among the conductive pattern layers 112a and 112b, to be grounded thereto, and can include conductive material such as metal. Furthermore, each of the conductive pins 121 may be a rod having a circular or polygonal section with respect to its longer axis, and may surround a device requiring electromagnetic wave shielding.

The conductive pins 121 have opposite ends on which solders 122a and 122b are applied, respectively, so that the conductive pins 121 can be electrically connected to the grounding wirings 112b, or to the conductive plate 130. Further, each conductive pin 121 has a height higher than the electric parts 140 and 150, and can be disposed between the electric parts 140 and 150 in such a manner that the conductive pins 121 surround the electric parts 140 and 150.

The molding member 160 can be formed on the insulation layer 160 by using an epoxy molding in such a manner that the conductive pins 121 and the electric parts 140 and 150 are buried therein. The molding member 160 tightly surrounds the conductive pins 121, thereby fixedly holding the conductive pins. Additionally, the molding member 160 covers the electric parts 140 and 150, thereby shielding electromagnetic waves.

However, each conductive pin 121 has an upper surface exposed to an upper part of the molding member 160. The conductive plate 130 is disposed on the molding member 160 so as to enable the conductive pins 121 to be electrically connected to each other. The conductive plate 130 can be electrically and physically connected to the conductive pins 121 through a process, such as a reflow process.

The present invention includes a plurality of the grounded conductive pins and the molding member in which the conductive pins and the electric parts are buried, thereby providing the electric circuit package which can minimize electromagnetic wave interference despite its minimized volume.

While the invention has been shown and described with reference to certain exemplary embodiments thereof, it will be understood by those skilled in the art that various changes in form and details may be made therein without departing from the spirit and scope of the invention as defined by the appended claims.

What is claimed is:

1. An electric circuit package comprising:
a printed circuit substrate having an insulating layer and conductive pattern layers formed on an upper surface of the insulating layer;
at least one of electronic parts disposed on an upper surface of the printed circuit substrate;
at least one of conductive pins electrically coupled to an conductive pattern layer to provide grounding among the conductive pattern layers; and
a molding member formed on the insulating layer in such a manner that the conductive pins and the electric parts are buried in the molding member, wherein each conductive pin has an upper surface exposed to an upper part of the molding member.

2. The electric circuit package as claimed in claim 1, further comprising a conductive plate disposed on an upper surface of the molding member in such a manner that the conductive plate is electrically coupled to the conductive pins.

3. The electric circuit package as claimed in claim 1, wherein each conductive pin has a height higher than the electric parts.

4. The electric circuit package as claimed in claim 1, wherein each conductive pin is coupled to the conductive plate and the corresponding conductive pattern layer by solders applied on an upper surface and a lower surface of each conductive pin.

5. The electric circuit package as claimed in claim 1, wherein the conductive pins are disposed between the electric parts.

6. The electric circuit package as claimed in claim 1, wherein the conductive pins are arranged so as to surround the electric parts.

7. The electric circuit package as claimed in claim 1, wherein the electric parts are electrically coupled to the conductive pattern layers by soldering or wiring process.

8. The electric circuit package as claimed in claim 1, wherein each of the conductive pins comprises a rod having a circular or polygonal section with respect to its longer axis.

9. The electric circuit package as claimed in claim 1, wherein each of the conductive pins surrounds a device requiring electromagnetic wave shielding.

10. The electric circuit package as claimed in claim 1, wherein the molding member is formed on the insulation layer using an epoxy molding.
